(19) United States
(12) Patent Application Publication
(10) Pub. No.: US 2025/0300454 A1
(43) Pub. Date: Sep. 25, 2025

(54) ELECTRONIC PROTECTIVE DEVICE

(71) Applicant: MAHLE International GmbH, Stuttgart (DE)

(72) Inventors: Peter Durn, Sempeter pri Gorici (SI); Zan Batistic, Sempeter pri Gorici (SI)

(21) Appl. No.: 19/088,833

(22) Filed: Mar. 24, 2025

(30) Foreign Application Priority Data
Mar. 25, 2024 (DE) 102024108408.1

(51) Int. Cl. H02H 9/04; H05K 1/11; H05K 1/18

(52) U.S. Cl. CPC H02H 9/042; H05K 1/113; H05K 1/181; H05K 2201/10174; H05K 2201/10545

(57) ABSTRACT

An electronic protective device for protecting electrical and/or electronic systems against overvoltage may include a printed circuit board (PCB) and a plurality of diode pairs connected in parallel. Each diode pair of the plurality of diode pairs may include a unidirectional suppressor diode and a bidirectional suppressor diode connected in series with the unidirectional suppressor diode. The PCB may have two mounting surfaces facing away from each other. The printed circuit board may include a plurality of conductor tracks. The unidirectional suppressor diode of each diode pair may be arranged on a first mounting surface of the two mounting surfaces of the printed circuit board. The bidirectional suppressor diode of each diode pair may be arranged on a second mounting surface of the two mounting surfaces of the printed circuit board.

### CROSS-REFERENCE TO RELATED APPLICATION

This application claims priority to German Patent Application No. DE102024108408.1, filed on Mar. 25, 2024, the contents of which is hereby incorporated by reference in its entirety.

### TECHNICAL FIELD

The present invention relates to an electronic protective device for protecting electrical and/or electronic systems against overvoltage.

### BACKGROUND

To improve the efficiency of battery electric vehicles, attempts are made to increase the voltage in an on-board electrical system that connects an electric traction battery to an electric traction motor. A higher voltage reduces the flowing currents and increases electrical efficiency. At the same time, the cable cross-sections required for this can be reduced despite the higher electrical power.

In a battery electric vehicle in particular, the vehicle electrical system is highly dynamic, meaning that current and voltage can fluctuate greatly. A protective device of the aforementioned type is used to protect components of the battery electric vehicle from damage caused by overvoltage.

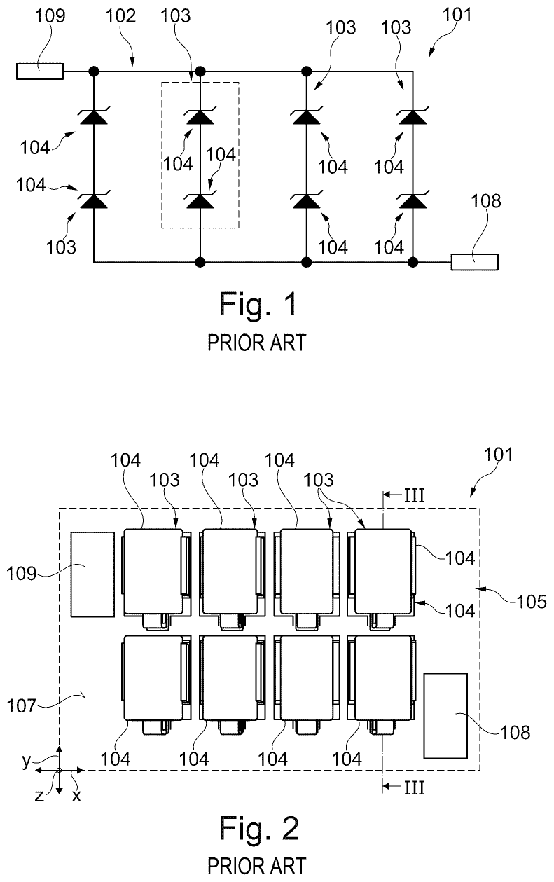

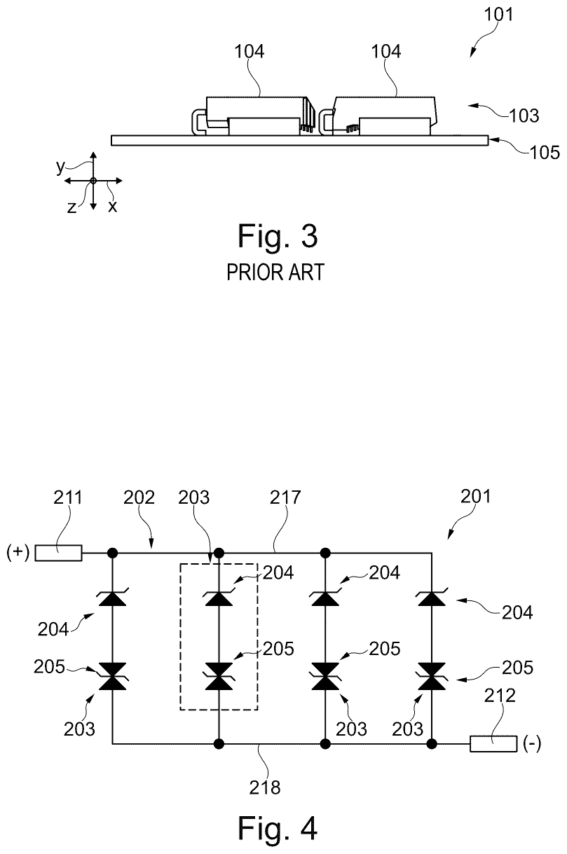

FIGS. 1 to 3 show a conventional electronic protective device 101 (Stand der Technik=prior art). FIG. 1 shows an electronic protective circuit 102, which is realized with the aid of the protective device 101. FIG. 2 shows a top view of the protective device 101, while FIG. 3 shows a cross-section of the protective device 101 corresponding to section lines III in FIG. 2. According to FIGS. 1 to 3, such a conventional protective device 101 comprises several diode pairs 103 connected in parallel, one of which is highlighted by a frame drawn with a broken line. Each diode pair 103 consists of exactly two unidirectional suppressor diodes 104, which are connected in series with each other. The diode pairs 103 are in turn connected in parallel. According to FIGS. 2 and 3, the protective device 101 also has a printed circuit board 105, which has a mounting surface 107 provided with conductor tracks 106, which in FIG. 2 faces the viewer and in FIG. 3 is arranged at the top or forms an upper side of the printed circuit board 105. In the conventional design of the protective device 101, all suppressor diodes 104 are now arranged on this mounting surface 107. The diode pairs 103 are connected in parallel with each other, while both suppressor diodes 104 are connected in series within the diode pairs 103. The protective device 101 has two electrical circuit board contacts 108 and 109, via which the protective device 101 can be electrically contacted, for example in order to integrate it into an electronic system that is to be protected against overvoltage. It can be seen that the conventional protective device 101 requires a comparatively large amount of installation space or space with respect to a longitudinal direction X and with respect to a transverse direction Y of the printed circuit board 105.

### SUMMARY

The present invention deals with the problem of providing an improved or at least another embodiment for an electronic protective device of the type described above, which is characterized by a reduced space requirement.

According to the invention, this problem is solved by the subject matter of the independent claim(s). Advantageous embodiments are the subject matter of the dependent claim(s).

The invention is based on the general idea of forming the diode pairs of the protective device with different suppressor diodes, namely with a unidirectional suppressor diode in combination with a bidirectional suppressor diode, which are connected in series within the respective diode pair. In addition, a printed circuit board is used which has two mounting surfaces with conductive tracks facing away from each other. Such a circuit board can also be referred to as a two-layer circuit board. For a particularly compact design, it is now proposed to arrange all unidirectional suppressor diodes on one mounting surface and all bidirectional suppressor diodes on the other mounting surface. In this way, the space requirement of the protective device can be significantly reduced, in particular virtually halved, compared to a conventional design. This is made possible in particular by the fact that the diode pairs are formed with the aid of a unidirectional suppressor diode and a bidirectional suppressor diode, as only this enables the series connection of the suppressor diodes within the respective diode pair with space-saving arrangement of the suppressor diodes on the mounting surfaces facing away from each other.

A suppressor diode is configured to protect against electrical overload and blocks from a predetermined limit voltage. Suppressor diodes are also known as TVS diodes, where TVS stands for Transient Voltage Suppressor. The printed circuit board is often referred to as a PCB, where PCB stands for Printed Circuit Board. The arrangement of the electronic components on the printed circuit board is also called PCB assembly and is often referred to as PCBA, where PCBA stands for PCB Assembly or Printed Circuit Board Assembly.

In the present context, a “configuration” is synonymous with a “arrangement” and/or “setup” and/or “programming”, so that the phrase “configured such that” is synonymous with the phrase “arranged and/or setup and/or programmed such that”.

According to an advantageous embodiment, the unidirectional suppressor diodes and the bidirectional suppressor diodes can each have, on an underside facing the respective mounting surface, a first electrical contact designed as a heat sink for electrical contacting of the respective suppressor diode and a second electrical contact arranged on the edge for electrical contacting of the respective suppressor diode. In other words, the unidirectional suppressor diodes and the bidirectional suppressor diodes are of identical design with regard to their electrical contacts, which favors space-saving accommodation on the two mounting surfaces. It is also worth noting that the respective first electrical contact is configured as a heat sink, i.e. it has a comparatively large thermal mass. This allows heat peaks occurring in the event of an overvoltage in the suppressor diode to be absorbed in order to protect the respective suppressor diode from overheating.

According to an advantageous further development, it may be provided that the printed circuit board is configured such that it electrically connects the first electrical contacts of the two suppressor diodes of the respective diode pair. Furthermore, the printed circuit board can be configured such that it electrically connects the second electrical contacts of the unidirectional suppressor diodes of the diode pairs in parallel with a first electrical printed circuit board contact for electrically contacting the protective device. In addition, the printed circuit board can be configured such that it electrically connects the second electrical contacts of the bidirectional suppressor diodes of the diode pairs in parallel with a second electrical printed circuit board contact for electrically contacting the protective device. In this way, a protective circuit is realized on the printed circuit board, which comprises the diode pairs connected in parallel and the suppressor diodes connected in series within the diode pairs. The special configuration of the suppressor diodes with a first contact on the underside and a second contact on one edge simplifies the circuit proposed here, while at the same time enabling a space-saving arrangement on the printed circuit board.

According to another further development, the printed circuit board can be configured in such a way that it electrically connects the first electrical contacts of the two suppressor diodes of the respective diode pair to one another through the printed circuit board. An extremely short connection path is realized through the printed circuit board, which is basically only formed by a thickness of the printed circuit board measured in a height direction of the printed circuit board. This allows a particularly compact configuration to be realized.

A configuration in which the first electrical contacts of the two suppressor diodes of the respective diode pair are electrically connected to each other through the printed circuit board using via-in-pad technology is particularly practical. With via-in-pad technology, not only is there an electrical connection from one mounting surface through the PCB to the other mounting surface, but a thermal connection is also created with the PCB as a thermal mass. This can be realized, for example, by creating an electrically conductive path that connects the two mounting surfaces through the PCB between the two mounting surfaces, i.e. at least partially integrated into the PCB material inside the PCB. Such a path is usually realized using an electrically conductive material, in particular copper, which, in addition to good electrical conductivity, also has good thermal conductivity. This means that electrical energy and thermal energy can be transferred via the path, with the heat essentially being conducted into the material of the printed circuit board. Via-in-pad technology therefore uses the printed circuit board as a heat sink that can absorb the heat that can be generated at the suppressor diodes under high loads.

In another advantageous embodiment, it may be provided that the printed circuit board has first conductive tracks on the one or first mounting surface which are configured such that they electrically connect the second electrical contacts of the unidirectional suppressor diodes of the diode pairs in parallel with the first electrical printed circuit board contact. In addition, the printed circuit board may have second conductive tracks on the other or second mounting surface, which are configured such that they electrically connect the second electrical contacts of the bidirectional suppressor diodes of the diode pairs in parallel with the second electrical printed circuit board contact. In this way, the two mounting surfaces are used to realize a particularly compact interconnection of the suppressor diodes, whereby the protective device can be realized in a compact manner overall.

It may be useful for the first PCB contact to be formed on one or the first mounting surface, while the second PCB contact is formed on the other or second mounting surface. This measure also supports a particularly compact design for the protective device.

According to a preferred embodiment, the printed circuit board can be configured to be flat so that it defines a printed circuit board plane and a height direction perpendicular to the printed circuit board plane. The suppressor diodes of all diode pairs can now be arranged on the printed circuit board in such a way that the first contacts of the suppressor diodes of the respective diode pair on the printed circuit board are arranged congruently to each other in the height direction. This allows a particularly space-saving arrangement to be realized, while at the same time ensuring extremely short distances for contacting the first contacts of the suppressor diodes within the respective diode pair.

In another embodiment, the suppressor diodes of all diode pairs can be arranged on the printed circuit board in such a way that the second contacts of the suppressor diodes of the respective diode pair on the printed circuit board are arranged congruently to each other in the height direction. This enables a symmetrical design of the conductor paths on the two mounting surfaces, which simplifies the cable routing and makes the protective device particularly compact overall.

According to another advantageous embodiment, the suppressor diodes of all diode pairs can be arranged on the printed circuit board in such a way that the suppressor diodes of the respective diode pair on the printed circuit board are arranged congruently to one another in the height direction. In this embodiment, the unidirectional suppressor diodes and the bidirectional suppressor diodes are essentially geometrically and/or optically identical. The congruent arrangement of the suppressor diodes within the respective diode pair with respect to the height direction results in a particularly compact design for the protective device.

In another embodiment, the printed circuit board can be configured to be elongated, in particular rectangular, so that it has a longitudinal direction running perpendicular to the height direction and a transverse direction running perpendicular to the height direction and perpendicular to the longitudinal direction. All pairs of diodes can now be arranged next to each other on the PCB in the longitudinal direction. This measure also favors a compact design of the protective device.

According to an advantageous further development, it can be provided that the suppressor diodes have a rectangular cross-section perpendicular to the height direction and thus two longitudinal edges running parallel to the longitudinal direction and two transverse edges running parallel to the transverse direction. Conveniently, the second contacts of the suppressor diodes can each be formed on a longitudinal edge and protrude from the longitudinal edge in the transverse direction. In addition, the suppressor diodes can be arranged on the printed circuit board in such a way that the second contacts of all suppressor diodes are arranged on the same side of the respective suppressor diode with respect to the transverse direction. This allows the suppressor diodes of neighboring diode pairs to be arranged relatively close to each other with respect to the longitudinal direction, making the protective device particularly compact.

Further important features and advantages of the invention are apparent from the sub-claims, from the drawings and from the associated description of the figures with reference to the

### DRAWINGS

It is to be understood that the features mentioned above and those to be explained below are usable not only in the combination indicated in each case, but also in other combinations or in a stand-alone position, without departing from the scope of the invention as defined by the claims. Components of a superordinate unit, such as a device, an apparatus or an arrangement, mentioned above and to be mentioned below, which are designated separately, can form separate parts or components of this unit or can be integral areas or sections of this unit, even if this is shown differently in the drawings.

Preferred embodiments of the invention are shown in the drawings and are explained in more detail in the following description, with identical reference signs referring to identical or similar or functionally identical components.

### BRIEF DESCRIPTION OF THE DRAWINGS

It shows, in each case schematically,

FIG. 1 is a highly simplified circuit diagram of a protective circuit of a protective device in a prior art embodiment,

FIG. 2 is a top view of the protective device in a prior art embodiment,

FIG. 3 shows a cross-section of the protective device according to sectional lines III from FIG. 2 in the embodiment according to the state of the art,

FIG. 4 shows a highly simplified circuit diagram of a protective circuit of a protective device in an embodiment according to the invention,

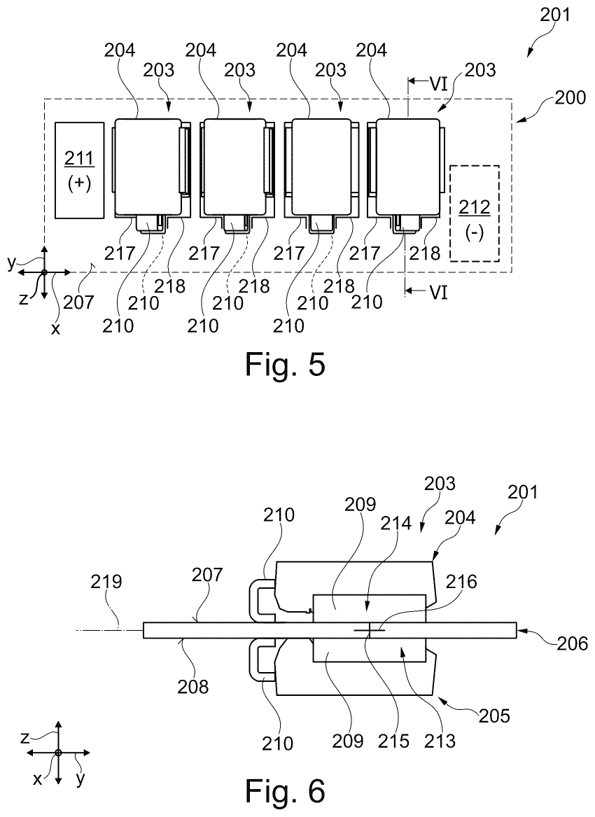

FIG. 5 shows a top view of the protective device in an embodiment according to the invention,

FIG. 6 shows a cross-section of the protective device according to sectional lines VI in FIG. 5 in the embodiment according to the invention.

### DETAILED DESCRIPTION

According to FIGS. 4 to 6, an electronic protective device 201, which serves to protect electrical and/or electronic systems against overvoltage, comprises a protective circuit 202, which is shown in simplified form in FIG. 4. The protective device 201 or the protective circuit 202 has several diode pairs 203, one of which is highlighted in FIG. 4 by means of a frame drawn with a broken line. The diode pairs 203 are connected in parallel within the protective circuit 202. Each diode pair 203 consists of exactly one unidirectional suppressor diode 204 and exactly one bidirectional suppressor diode 205. Within the respective diode pair 203, the unidirectional suppressor diode 204 and the bidirectional suppressor diode 205 are connected in series.

The protective device 201 is also equipped with a two-layer printed circuit board 206, which has two mounting surfaces 207 and 208 facing away from each other in a height direction Z of the printed circuit board 206. The two mounting surfaces 207, 208 are also referred to below as first mounting surface 207 and second mounting surface 208. In FIG. 5, the first mounting surface 207 faces the viewer, while the second mounting surface 208 faces away from the viewer. In FIG. 6, the first mounting surface 207 is located at the top or on the upper side of the printed circuit board 206, while the second mounting surface 208 is located at the bottom or on a lower side of the printed circuit board 206.

In the protective device 201 presented here, all unidirectional suppressor diodes 204 are now arranged on the one or first mounting surface 207, while all bidirectional suppressor diodes 205 are arranged on the other or second mounting surface 208. Accordingly, only the unidirectional suppressor diodes 204 arranged on the first mounting surface 207 facing the viewer are recognizable in FIG. 5, since the bidirectional suppressor diodes 205 are located on the second mounting surface 208 facing away from the viewer.

According to FIG. 6, the unidirectional suppressor diodes 204 and the bidirectional suppressor diodes 205 each have a first electrical contact 209 for electrically contacting the respective suppressor diode 204, 205 and a second electrical contact 210 for electrically contacting the respective suppressor diode 204, 205. In each case, the first contacts 209 are designed as heat sinks and are formed on an underside of the respective suppressor diode 204, 105 facing the respective mounting surface 207, 208. In contrast, the second contacts 210 are formed on the edge of the respective suppressor diode 204, 205, i.e. on an edge of the respective suppressor diode 204, 205. The first contact 209, which is designed as a heat sink, has a comparatively large thermal mass. In particular, the first contact 209 has more metal than it requires for the maximum current flowing during proper operation.

In the protection device 201 presented here, the printed circuit board 206 is configured to electrically connect the first electrical contacts 209 of the two suppressor diodes 204, 205 of the respective diode pair 203. In addition, the printed circuit board 206 is configured such that it electrically connects the second electrical contacts 210 of the unidirectional suppressor diodes 204 of the diode pairs 203 in parallel with a first electrical printed circuit board contact 211, which is used for electrically contacting the protective device 201. This is preferably a positive contact or plus contact, which is indicated by a plus symbol (+) in FIGS. 4 and 5. Furthermore, the printed circuit board 206 can be configured such that it electrically connects the second electrical contacts 210 of the bidirectional suppressor diodes 205 of the diode pairs 203 in parallel with a second electrical printed circuit board contact 212, which is also provided for making electrical contact with the protective device 201. This second printed circuit board contact 212 is appropriately a negative contact or minus contact and is indicated in FIGS. 4 and 5 by a minus symbol (−). The unidirectional suppressor diodes 204 are connected here in such a way that they are arranged in the direction of the first printed circuit board contact 211, i.e., in the direction of the positive contact (+), and in the direction of the respective bidirectional suppressor diode 205 in a blocking manner.

For a particularly compact design, the printed circuit board 206 can be configured such that it electrically connects the first electrical contacts 209 of the two suppressor diodes 204, 205 of the respective diode pair 203 to each other through the printed circuit board 20. This allows the two suppressor diodes 204, 205 of the respective diode pair 203 to be arranged close to each other, which favors a compact design for the protective circuit 202 or for the protective device 201. In particular, it may be provided that the electrical contacts 209 of the two suppressor diodes 204, 205 of the respective diode pair 203 are electrically connected to each other through the printed circuit board 206 by means of via-in-pad technology 213. The via-in-pad technology 213 is indicated in FIG. 6 by a conductor path 214, which has an electrical conductor 215 and a heat conductor 216. The electrical conductor 215 electrically connects the two first contacts 209 to each other through the printed circuit board 206. The heat conductor 216 is integrated into the material of the printed circuit board 206 and is located between the mounting surfaces 207, 208 with respect to the height direction Z of the printed circuit board 206 and is spaced apart from these in the height direction Z. The heat conductor 216 is coupled to the electrical conductor 215 in a heat-transferring manner. For example, the electrical conductor 215 and the heat conductor 216 form a coherent structure and consist of the same electrically conductive and thermally conductive material, such as copper.

The printed circuit board 206 has first conductive tracks 217 on the first mounting surface 207, which are configured to electrically connect the second electrical contacts 210 of the unidirectional suppressor diodes 204 of the diode pairs 203 in parallel with the first electrical printed circuit board contact 211. Further, the printed circuit board 206 has second conductive traces 218 on the second mounting surface 208 configured to electrically connect the second electrical contacts 210 of the bidirectional suppressor diodes 205 of the diode pairs 203 in parallel with the second electrical printed circuit board contact 212. In FIG. 5, the second conductive paths 218 and the second electrical contacts 210 of the bidirectional suppressor diodes 205 are turned away from the viewer so that the associated reference lines are shown interrupted. According to FIG. 5, it can now be expediently provided that the first printed circuit board contact 211 is formed on the first mounting surface 207, while the second printed circuit board contact 212 is formed on the second mounting surface 208. Since the second mounting surface 208 in FIG. 5 is turned away from the observer, the second printed circuit board contact 212 is only shown with a broken line. In another embodiment, the two PCB contacts 211 and 212 may be formed on the same mounting surface 207 or 208.

According to the embodiment shown here, the printed circuit board 206 is preferably configured to be flat and in particular rectangular, so that the printed circuit board 206 defines a printed circuit board plane 219 indicated in FIG. 6 and a height direction Z perpendicular to the printed circuit board plane 219. The suppressor diodes 204, 205 of all diode pairs 203 can now be arranged on the printed circuit board 206 in such a way that the first contacts 209 of the suppressor diodes 204, 205 of the respective diode pair 203 on the printed circuit board 206 are arranged congruently to one another with respect to the height direction Z. In addition, the suppressor diodes 204, 205 of all diode pairs 203 can be arranged on the printed circuit board 206 in such a way that the second contacts 210 of the suppressor diodes 204, 205 of the respective diode pair 203 on the printed circuit board 206 are also arranged congruently with one another in the height direction Z.

In the embodiment shown here, it is also provided that the unidirectional suppressor diodes 204 and the bidirectional suppressor diodes 205 are configured geometrically and/or optically almost identically, so that they have at least identical base areas or cross-sections. With such a geometrically and/or optically identical design of the unidirectional suppressor diodes 204 and the bidirectional suppressor diodes 205, the suppressor diodes 204 and 205 of all diode pairs 203 can be arranged on the printed circuit board 206 in such a way that the suppressor diodes 204, 205 of the respective diode pair 203 are arranged on the printed circuit board 206 congruently with one another in the height direction Z. This design can be seen in particular in FIGS. 5 and 6.

Conveniently, the printed circuit board 206 can be configured, in particular rectangularly, so that it has a longitudinal direction X extending perpendicular to the height direction Z and a transverse direction Y extending perpendicular to the height direction Z and perpendicular to the longitudinal direction X. In FIG. 5, the longitudinal direction X extends horizontally, while the transverse direction Y extends vertically. The vertical direction Z is perpendicular to the drawing plane of FIG. 5. In FIG. 6, the transverse direction Y extends horizontally, while the vertical direction Z extends vertically. In FIG. 6, the longitudinal direction X is perpendicular to the plane of the drawing. In the example shown here, all pairs of diodes 203 are arranged next to each other in the longitudinal direction X on the printed circuit board 206.

In the example shown here, the suppressor diodes 204, 205 each have a rectangular cross-section perpendicular to the height direction Z, so that the respective suppressor diode 204, 205 each has two longitudinal edges running parallel to the longitudinal direction X and two transverse edges running parallel to the transverse direction. According to FIG. 5, the second contacts 210 of the suppressor diodes 204, 205 are each formed on a longitudinal edge, with the respective second contact 210 projecting from the respective longitudinal edge in the transverse direction Y. The suppressor diodes 204, 205 are arranged on the printed circuit board 206 in such a way that for all suppressor diodes 204, 205 the second contacts 210 are arranged on the same side of the respective suppressor diode 204, 205 with respect to the transverse direction Y. In the example of FIG. 5, all second contacts 210 on the unidirectional suppressor diodes 204 facing the observer are arranged on the horizontally extending lower longitudinal edge, so that they project downwards from the rectangular cross-section of the suppressor diode 204 in the transverse direction Y. The second contacts 210 of the bidirectional suppressor diodes 205 concealed in FIG. 5, which are arranged congruently with respect to the height direction Z, also project downwards from the lower longitudinal edge in the transverse direction Y, so that the congruent arrangement of the second contacts 210 with respect to the height direction Z results within the respective diode pair 203.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the phrase at least one of successive elements separated by the word “and” (e.g., “at least one of A and B”) is to be interpreted the same as the term “and/or” and as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

1. An electronic protective device for protecting electrical and/or electronic systems against overvoltage, comprising:
a plurality of diode pairs connected in parallel, each diode pair of the plurality of diode pairs including a unidirectional suppressor diode and a bidirectional suppressor diode connected in series with the unidirectional suppressor diode; and
a printed circuit board having two mounting surfaces facing away from each other, the printed circuit board including a plurality of conductor tracks;
wherein the unidirectional suppressor diode of each diode pair is arranged on a first mounting surface of the two mounting surfaces of the printed circuit board and the bidirectional suppressor diode of each diode pair is arranged on a second mounting surface of the two mounting surfaces of the printed circuit board.

2. The protective device according to claim 1, wherein each diode of each of the plurality of diode pairs includes a plurality of electrical contacts for electrical contacting of the respective diode, the plurality of electrical contacts including:
a first electrical contact configured as a heat sink and arranged on an underside of the respective diode facing the respective mounting surface of the printed circuit board; and
a second electrical contact arranged on an edge of the respective diode.

3. The protective device according to claim 2, wherein:
the printed circuit board electrically connects the first electrical contact of the unidirectional suppressor diode of a respective diode pair and the first electrical contact of the bidirectional suppressor diode of the respective diode pair to one another;
the printed circuit board electrically connects the second electrical contact of the unidirectional suppressor diode of each diode pair of the plurality of diode pairs in parallel with a first electrical printed circuit board contact for electrically contacting the protective device; and
the printed circuit board electrically connects the second electrical contact of the bidirectional suppressor diode of each diode pair of the plurality of diode pairs in parallel with a second electrical printed circuit board contact for electrically contacting the protective device.

4. The protective device according to claim 3, wherein the printed circuit board electrically connects the first electrical contact of the unidirectional suppressor diode of a respective diode pair and the first electrical contact of the bidirectional suppressor diode of the respective diode pair to one another through the printed circuit board.

5. The protective device according to claim 4, wherein the first electrical contact of the unidirectional suppressor diode of a respective diode pair and the first electrical contact of the bidirectional suppressor diode of the respective diode pair are electrically connected to one another through the printed circuit board by via-in-pad technology.

6. The protective device according to claim 3, wherein:
the printed circuit board includes, arranged on the first mounting surface, a plurality of first conductor tracks electrically connecting the second electrical contact of the unidirectional suppressor diode of each diode pair of the plurality of diode pairs in parallel with the first electrical printed circuit board contact; and
the printed circuit board further includes a plurality of second conductor tracks arranged on the second mounting surface, the plurality of second conductor tracks electrically connecting the second electrical contact of the bidirectional suppressor diode of each diode pair of the plurality of diode pairs in parallel with the second electrical printed circuit board contact.

7. The protective device according to claim 3, wherein:
the first printed circuit board contact is formed on the first mounting surface; and
the second printed circuit board contact is formed on the second mounting surface.

8. The protective device according to claim 3, wherein:
the printed circuit board is planar and defines i) a printed circuit board plane and ii) a height direction extending perpendicular to the printed circuit board plane; and
each diode of each of the plurality of diode pairs are arranged on the printed circuit board such that the first electrical contact of each diode of the respective diode pair are arranged congruently to one another in the height direction.

9. The protective device according to claim 8, wherein each diode of each of the plurality of diode pairs are arranged on the printed circuit board such that the second electrical contact of each diode of the respective diode pair are arranged congruently to one another in the height direction.

10. The protective device according to claim 8, wherein each diode of each of the plurality of diode pairs are arranged on the printed circuit board such that the unidirectional suppressor diode and the bidirectional suppressor diode of a respective diode pair are arranged congruently to one another in the height direction.

11. The protective device according to claim 8, wherein:
the printed circuit board is elongated and has i) a longitudinal direction extending perpendicular to the vertical direction and ii) a transverse direction extending perpendicular to the vertical direction and perpendicular to the longitudinal direction; and
the plurality of diode pairs are arranged next to each other on the printed circuit board in the longitudinal direction.

12. The protective device according to claim 11, wherein:
each diode of each of the plurality of diode pairs has a rectangular cross-section perpendicular to the vertical direction, two longitudinal edges extending parallel to the longitudinal direction, and two transverse edges extending parallel to the transverse direction;
the second electrical contact of each diode of each of the plurality of diode pairs is formed on and projects from one of the two longitudinal edges of the respective diode in the transverse direction; and
the second electrical contact of each diode of each of the diode pairs is arranged on the same side of the respective diode with respect to the transverse direction.

13. An electronic protective device for protecting electrical and/or electronic systems against overvoltage, comprising:
a printed circuit board (PCB) having a first mounting surface and a second mounting surface facing away from one another;
a plurality of unidirectional suppressor diodes arranged on the first mounting surface of the PCB;
a plurality of bidirectional suppressor diodes arranged on the second mounting surface of the PCB; and
a plurality of diode pairs connected in parallel;
wherein each of the plurality of diode pairs are defined by i) a respective unidirectional suppressor diode of the plurality of unidirectional suppressor diodes and ii) a respective bidirectional suppressor diode of the plurality of bidirectional suppressor diodes that is connected in series with the respective unidirectional suppressor diode.

14. The protective device according to claim 13, wherein each of the plurality of unidirectional suppressor diodes and each of the plurality of bidirectional suppressor diodes includes a plurality of electrical contacts for electrical contacting of the respective diode.

15. The protective device according to claim 14, wherein the plurality of electrical contacts includes:
a first electrical contact configured as a heat sink and arranged on an underside of the respective diode facing the respective mounting surface of the printed circuit board; and
a second electrical contact arranged on an edge of the respective diode.

16. The protective device according to claim 15, wherein the first electrical contact of the unidirectional suppressor diode of a respective diode pair and the first electrical contact of the bidirectional suppressor diode of the respective diode pair are electrically connected to one another via the PCB.

17. The protective device according to claim 15, wherein the second electrical contact of each of the plurality of unidirectional suppressor diodes is electrically connected in parallel with an electrical printed circuit board contact disposed on the first mounting surface of the PCB.

18. The protective device according to claim 17, wherein:
the PCB includes a plurality of conductor tracks arranged on the first mounting surface; and
the plurality of conductor tracks electrically connect the second electrical contact of each of the plurality of unidirectional suppressor diodes in parallel with the electrical printed circuit board contact disposed on the first mounting surface of the PCB.

19. The protective device according to claim 15, wherein the second electrical contact of each of the plurality of bidirectional suppressor diodes is electrically connected in parallel with an electrical printed circuit board contact disposed on the second mounting surface of the PCB.

20. The protective device according to claim 19, wherein:
the PCB includes a plurality of conductor tracks arranged on the second mounting surface; and
the plurality of conductor tracks electrically connect the second electrical contact of each of the plurality of bidirectional suppressor diodes in parallel with the electrical printed circuit board contact disposed on the second mounting surface of the PCB.
